(19) United States
(12) Patent Application Publication
(10) Pub. No.: US 2012/0325293 A1
(43) Pub. Date: Dec. 27, 2012

(54) SOLAR MODULE HAVING IMPROVED CORROSION PROPERTIES

(75) Inventors: Kurt Nattermann, Ockenheim (DE); Urban Weber, Weiler Bei Bingen (DE); Peter Zachmann, Osthofen (DE); Ingo Schwirtlich, Miltenberg (DE); Harry Engelmann, Ingelheim (DE); Uwe Fliedner, Kleinostheim (DE)

(73) Assignee: SCHOTT AG, Mainz (DE)

(21) Appl. No.: 13/516,955

(22) PCT Filed: Dec. 17, 2010
(86) PCT No.: PCT/EP2010/070150

§ 371 Date: Sep. 11, 2012

(30) Foreign Application Priority Data
Dec. 18, 2009 (DE) 10 2009 059 105.2

(51) Int. Cl. H01L 31/048

(52) U.S. Cl. 136/251

(57) ABSTRACT

Solar modules are provided that include a front pane, an inter layer into which solar cells are embedded, and at least one back side foil, which increases the life span of the solar modules. The at least one back side foil is provided with holes having a density of at most 0.2 cm⁻².

The present invention relates to solar modules having a longer life time due to the particular configuration of at least one of its back side foils.

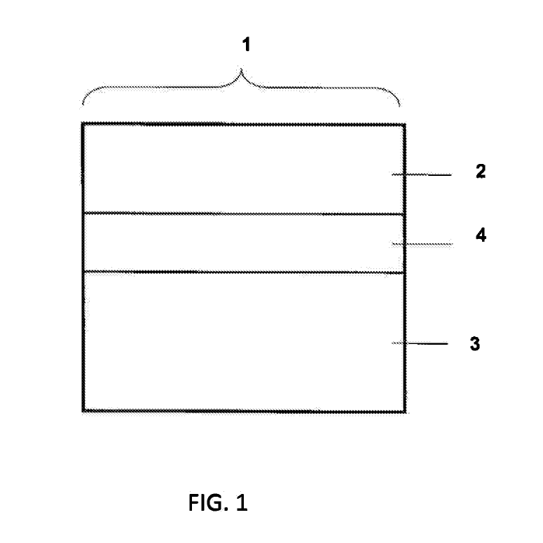

Solar modules may e.g. have an assembly according to FIG. 1. Thus, solar modules may comprise a front pane 2, an inter layer 4 and back side foils 3. At least two back side foils may be present as a laminate.

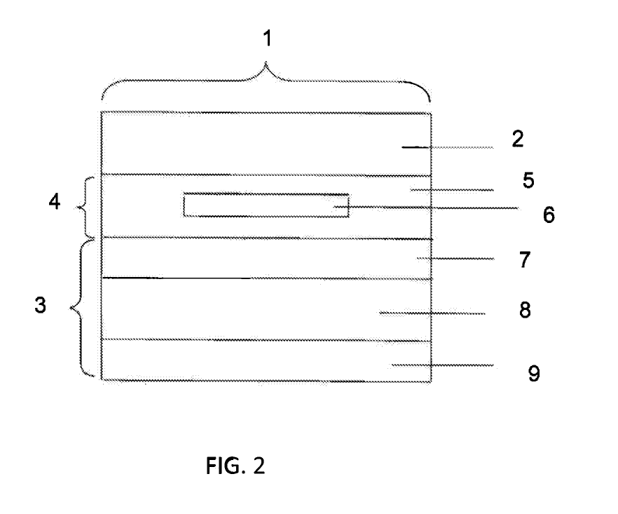

Mostly, the inter layer 4 consists of (an) embedment material layer(s) 5 as well as the solar cells 6 as shown in FIG. 2. The embedment material layers 5 may also be laminates, thus consist of several single layers. Normally, the back side foils 3 are adjacent to the inter layer 4. For example, the back side foils consist of a weatherproof foil 7, an insulation foil 8 and a further weatherproof foil 9 as shown in FIG. 2.

Basically, the solar modules according to the present invention have a similar assembly. They are characterized by a particular configuration of at least one back side foil which results in considerably advantageous properties.

Solar cells for direct conversion of solar energy into electric current should be enclosed for mechanic protection, e.g. against hail, damages during installation or maintenance, for protection against corrosive environmental influences as well as for achieving the required electric safety. The essential components for the enclosure (also encapsulation) are a transparent front pane, embedment materials into which the solar cells are embedded or cast and which are transparent at least between the front pane and the solar cells, and a back side foil at the back side of the solar module. The composite of front pane, embedment materials, solar cells, integrated components and back side foils as well as optionally a frame is referred to as solar module. In this context, transparent means that a material is penetrable for electromagnetic radiation, wherein this radiation comprises wave lengths which allow a conversion of the electromagnetic radiation into electric energy by means of the solar cells which are integrated in the solar modules.

Normally, front panes consist of soda silicate glass having a thickness of several mm so that the required bearing capacity can be achieved and the front pane is suitable for increasing the mechanical strength.

Polymeric materials, such as e.g. EVA (ethylene vinyl acetate), which are reasonably priced are suitable as embedment materials. Normally, the embedment materials are used in the form of foils having thicknesses of for example 0.4 to 0.8 mm. But EVA used as an encapsulation material has several disadvantages resulting in effects with respect to the quality of the modules:
EVA contains a peroxide as a cross-linking initiator. The peroxide which is not consumed during the lamination process may decompose the EVA and oxidize other components in the solar module.
at the relatively high processing temperatures (lamination temperatures of up to 150° C.) EVA forms acetic acid and acetates which may corrode other components, for example metallic components, in the solar module.
furthermore, EVA releases corrosive decomposition products during the operation of the solar modules. The reasons for that may be thermo-oxidative (oxidation by heat), photo-oxidative (oxidation by UV radiation of the sunlight) and chemical processes, for example due to said residues of peroxide.

Here, it is assumed that in the case of chemical and photo-oxidative processes also the humidity which is present in the foil might play a role.

Compared with the embedment material EVA similar negative effects may arise with the use of other transparent embedment materials for solar modules, such as e.g. PVB (polyvinyl butyral).

A lot of types of back side foils are known, such as for example TPT® laminates (Tedlar-PET-Tedlar, Tedlar=polyvinyl fluoride (PVF); PET=polyethylene tetraphthalate) and TAP® laminates (Tedlar-aluminum-PET). The back side foils have to fulfil several functions, in particular the electric insulation of the solar cells against influences from outside, the protection of the solar cells against environmental influences as well as the mechanical protection of the solar cell. A further requirement for the back side foils of polymeric materials results from the lamination process, because at the high lamination temperatures (in the case of EVA normally this temperature is 140° C. and higher) also the back side foils will soften. This results in the danger of piercing the back side foil(s) with the electric wiring of the solar cells which results in loss of the electric safety. Thus, the foil materials should soften as little as possible also in the case of said temperatures.

Known back side foils have the disadvantage to constitute high permeation barriers for decomposition products present and/or created in the solar modules.

In the past, a lot of attempts have been made to reduce the concentration of corrosive substances in solar modules. U.S. Pat. No. 5,447,576 describes an assembly and a method for the encapsulation of solar cells. The thermally caused discoloration should be reduced. The embedment material, such as e.g. EVA, is doped with so-called light stabilizers. An analysis of the mechanisms of action of stabilizers shows that they predominantly act as selective absorbers and oxidants. Nevertheless, the embedment material releases corrosive decomposition products which form a deposit on the front pane.

DE 698 19 157 T2 discloses an encapsulation material which is intended for use in solar modules in the form of a laminate having at least three layers of metallocene polyethylene and polyethylene copolymers, wherein the outer thin layers of the laminate contain UV stabilizers against thermo-oxidative and photo-oxidative decomposition. These embedment materials are more expensive than e.g. EVA or PVB. Despite the use of UV stabilizers also in the case of such transparent polymeric materials under the influence of UV light over a long time certain decomposition takes place, also due to the presence of corroding substances.

US 2008/185033 describes a solar module in which between the embedment material and the back side foil a reflective foil is embedded for increasing the solar efficiency. This foil may permanently be bonded with the back side foil in the form of a combined laminate. This reflective foil is absolutely impermeable for the breakdown products developed in the solar module. For allowing the removal of the developed breakdown products, the reflective foil is perforated in certain areas. This perforation consists of 10 to 1000 holes per cm² having a diameter of 1 to 10 μm and is located only in certain, namely central areas below the solar cells. These solar modules have essential disadvantages. Technically, the given diameters and densities of the holes can only be realized with very thin foils. Such small holes in the pm range are failure-prone, reduce the strength and rigidity of the foil and result in reduced mechanical stability of the whole solar module. In addition, the very small holes may be present in a very high amount, as mentioned, of up to 1000 holes per cm² of the foil. In addition, the reflective (metallic) foil is in close and large-area contact with the embedment material, for example EVA, having electric conductivity which has to be considered. Thus, the danger of electric short-circuits or power-reducing electric leak current short-circuits in the module arises. Furthermore, the reflective foil can fulfil its function only, when it is not perforated in the area of the interspaces. However, this is connected with a lot of efforts with respect to the technical production thereof, because normally the foils show strong anisotropic shrinkage during the lamination of the modules, and thus it is difficult before the lamination process to exactly trim and fit the foils.

WO 05/035 243 A1 describes back side foils for solar modules consisting of a laminate of a weatherproof PVF or PVDF foil (polyvinylidene fluoride) and at least one further foil. This laminate has the disadvantage of having a high permeation resistance for corrosive products in the solar modules.

WO 03/107 438 A1 discloses a back side foil intended for use in solar modules which has a considerably higher melting temperature than the encapsulation material so that the risk of piercing the foil is reduced. Furthermore, the foil consists of ionomer/nylon composites, Zn ionomers or Sorlyn® foils. The described back side foils have the disadvantage of having a high permeation resistance for corrosive decomposition products in the solar module, as already known from other foils of prior art. Therefore, the embedment materials currently available result in the search for methods for removing the corrosive decomposition products from the solar module. The removal of the corrosive substances through the front pane is not possible. The removal of the corrosive decomposition products via the frames of the modules is inefficient in the case of large modules due to the long diffusion ways. The removal of the corrosive substances via the back side foil is an unsolved task till today.

Thus, there exists a great demand for solar modules in which the concentration of corrosive substances is reduced. Substances promoting corrosion should be allowed to escape, wherein the technical measures which are required for that should be realizable in a simple and economic manner. Thus, solar modules should be provided which on the one hand can be manufactured in a cost-effective and simple way and on the other hand have a longer life time.

Surprisingly, according to the present invention it has been achieved to solve this object. The back side foil(s) is/are able to allow the escape of corrosive substances from the solar modules and is/are not sensitive with respect to environmental influences. Further, mechanical protection is guaranteed.

The melting temperature of the starting materials of the foils is suitable for the lamination process. All advantageous properties according to the present invention can be achieved with low-priced measures, thus a solar module according to the present invention with a longer life time can be produced in a simple and cost-effective manner.

The present invention relates to a solar module, comprising a front pane, an inter layer, into which solar cells are embedded, and at least one back side foil, wherein at least one back side foil is perforated. Preferably, the holes of the perforation are circular holes and they have a radius of at least 0.2 mm and at most 1 mm.

The solar module according to the present invention has sufficient bearing capacity, high thermal stability besides the reduced concentration of corrosive substances within the module. In the case of a back side foil laminate present in the module at least a part of a foil is perforated.

Furthermore, it is advantageous, when those back side foil which is the highest diffusion barrier for corrosive decomposition products of the plastic materials used has holes. Depending on the conditions, a person skilled in the art will design the hole accordingly, which allows a suitable form being different from the preferred embodiment.

According to the present invention it is preferable that the radius of the holes is at least 0.2 mm so that a sufficiently large area for gas exchange is provided. Preferably, the radius of the holes is higher than 0.5 mm to reduce the risk of clogging, e.g. with dirt particles. Further preferable according to the present invention is a radius of the holes of 0.7 mm, whereby the percolation of dirt particles, for example up to the layers of embedment material, can be reduced.

According to the present invention it is preferable that the radius of the holes is at most 1 mm so that the strength of the foil is maintained. Furthermore, with this unevenness on the back side of the module caused by series connectors used can be compensated. Series connectors are electric connectors between the cells. Normally, they consist of tinned copper with rectangular cross section.

According to the present invention it is preferable that a hole in at least one back side foil of the solar module has an area of 0.1 mm² to 3.3 mm², preferably 0.25 mm² to 3 mm³. When the hole has an area of 0.7 mm² to 1.6 mm² which range is more preferable, then on the one hand the corrosive decomposition products can escape from the solar module and on the other hand the clogging of the holes, e.g. by dirt, can be reduced. Such an embodiment is more preferable, as already mentioned.

According to the present invention it is also preferred that the density of the holes in at least one back side foil of the solar module is at least 0.02 cm⁻² and at most 0.2 cm⁻². Preferably, the density of the holes is between 0.04 cm⁻² and 0.1 cm⁻². On the one hand, corrosive decomposition products can escape from the solar module and on the other hand the clogging of the holes can be reduced.

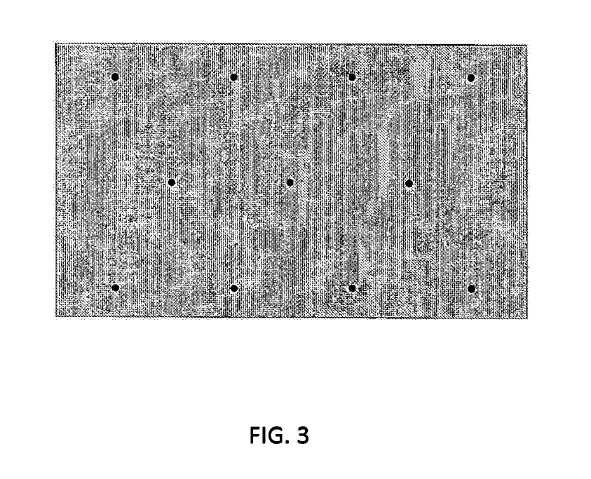

Substantially, the holes are regularly arranged and may e.g. be arranged in rectangular or hexagonal manner. Hexagonal arrangement is preferable, because this embodiment compared with the rectangular arrangement of the holes results in higher tear resistance. In addition, also in the case of a lower density of the holes the same permeation effect with respect to the escape of corrosive substances can be achieved. FIG. 3 shows the principle.

According to the present invention, preferably the whole area of the back side foil which serves for covering is provided with a respective arrangement of holes, also referred to as perforation.

Preferably, the solar module according to the present invention comprises at least one weatherproof foil and one insulation foil. Both kinds of foils are back side foils. These back side foils may be arranged differently to each other. For example two weatherproof back side foils may be arranged on one side of the insulation foil each. In an embodiment which is more preferable according to the present invention the assembly of “weatherproof foil, insulation foil, weatherproof foil” is a symmetric assembly, i.e. the weatherproof foils are arranged on one side of the insulation foil each and have the same thickness, as shown in FIG. 2.

It is preferable according to the present invention that the weatherproof foil or both weatherproof foils are provided with holes according to the present invention and thus are permeable for corrosive substances, in particular acetic acid. The preferred thicknesses of the weatherproof foils are between 10 and 100 μm and thus they are in principle a low diffusion barrier for corrosive substances. Thus, the density of the holes per cm² of the foil may be in the range which is preferable according to the present invention. The same belongs to the area of the holes. The smaller those two values can be kept, the better for the tear resistance of the foils, which is advantageous.

It is also preferable that the solar module according to the present invention comprises an insulation foil provided with holes so that the diffusion barrier for corrosive substances can further be reduced. When in addition at least one weatherproof foil is provided with holes, then the diffusion barrier can further be reduced in addition. In the sense of the invention, in particular acetic acid having corrosive properties should escape from the solar module. According to a particular embodiment of the invention, the outermost weatherproof foil is not perforated. So the infiltration of dirt particles can excellently be prevented.

So according to the present invention, at least one back side foil is perforated. It is further preferred that the front pane of the solar module is not perforated. In one embodiment the inter layer is not perforated. In a particularly preferable embodiment the back side foil is the only layer in the solar module which is perforated. In this case perforated should mean that the respective layer comprises a plurality of holes. When for example a layer comprises only one single hole, e.g. for realizing an electric contact, then this is not considered as “perforated”. The same belongs to embodiments, where the solar module comprises continuous holes, e.g. for screw insertion. But of course, modules according to the present invention may also comprise single larger holes, e.g. for mounting the module or for realizing a contact, besides perforated layers, thus layers comprising a lot of small holes.

It is obvious that preferably also the solar cells in the solar module are not perforated, because this would compromise the efficiency of the module. But the fact that the solar cells are not perforated does not exclude, as already mentioned above, that the solar cells nevertheless may comprise single holes for realizing an electric contact, as may be the case with solar cells of the back side contact type.

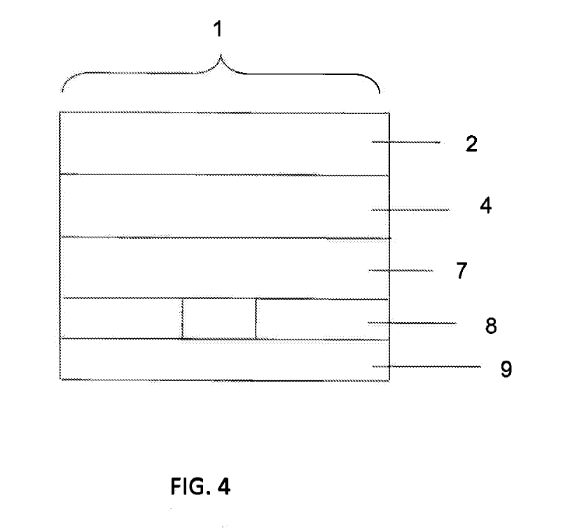

A special embodiment of the present invention is characterized by an insulation foil 8 which is provided with holes and preferably consists of PET. Preferably at least one weatherproof foil of the back side foil of the solar module consists of PVF. The solar cell 6 is embedded in EVA and the front pane 2 consists of glass. FIG. 4 shows the principle. The weatherproof foil which preferably consists of PVF has a thickness of 10 μm to 100 μm. The insulation foil which preferably consists of PET has a thickness of 50 μm to 1000 μm. Preferably, the PET foil is thicker than 300 μm, wherein thicknesses in the range of 300 μm to 350 μm are suitable. Ranges for example for suitable thicknesses of the PET foils are from 50 μm to 350 μm, 100 μm to 300 μm, also 50 μm to 300 μm or 100 μm to 350 μm.

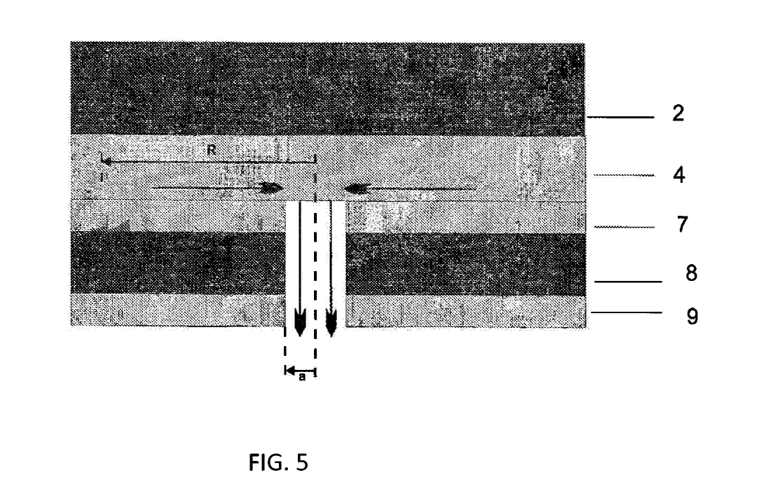

According to a further preferable embodiment all back side foils are provided with holes. FIG. 5 shows the principle. The back side foils are provided with circular holes as perforations, wherein the radius a of which is high enough to allow the escape of corrosive substances, such as e.g. acetic acid. R describes the zone of influence of the hole, i.e. the corrosive substances which are present around the hole in a circular area with the radius R will diffuse into the direction of the hole. Since the thickness of the embedment material layer is preferably smaller than R, a rotation-symmetric two-dimensional diffusion is existent. The inter layer 4 is adjacent to the back side foils and the front pane 2 is adjacent to this layer.

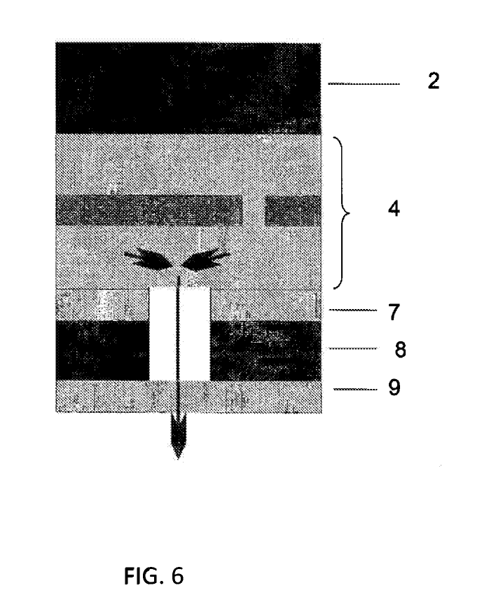

FIG. 6 shows the principle of a further preferable embodiment of a solar module according to the present invention, wherein a weatherproof foil 7 and the insulation foil 8 are provided with holes. The exterior weatherproof foil 9 is not perforated. The inter layer 4 is adjacent to the back side foils and the front pane 2 is adjacent to this layer.

### EXAMPLE

An example for the production of a solar module with a back side foil according to the present invention is described below:

As a front pane a commercially available solar glass is used. The adjacent inter layer consists of normal embedment materials (ethylene vinyl acetate, polyvinyl butyral) into which the solar cells with series connection and string connectors are embedded. A string connector connects the single strings within the module and normally consists of tinned copper with rectangular cross section. The whole thickness of the embedment material layer (5) is between 500 μm and 2000 μm. The back side foils (3) are formed as a laminate and consist of a weatherproof foil (7) of polyvinyl fluoride, an insulation foil (8) of polyethylene terephthalate (PET) and a further weatherproof foil (9) of polyvinyl fluoride (PVF). The final foil (9) of polyvinyl fluoride has a thickness of 20 to 50 μm. The insulation foil of polyethylene terephthalate has a thickness in the range of between 150 μm and 300 μm. The foil of polyethylene terephthalate is provided with holes having a circular shape and a radius of 0.5 mm. The distance between two circular holes is 2 cm. The holes are arranged in a hexagonal manner, as shown for example in FIG. 3.

### LIST OF REFERENCE SIGNS

1 solar module
2 front pane
3 back side foil(s)
4 inter layer
5 embedment material layer
6 solar cells
7 weatherproof foil
8 insulation foil
9 weatherproof foil
R zone of influence of the hole
a radius of the hole

1-22. (canceled)

23. A solar module, comprising:
a front pane;
an inter layer into which solar cells are embedded; and
at least one back side foil, wherein the at least one back side foil is provided with holes having a density of at most 0.2 cm⁻².

24. The solar module according to claim 23, wherein the holes comprise a hole having an area between 0.1 mm² to 3.3 mm².

25. The solar module according to claim 24, wherein the hole is a circular hole.

26. The solar module according to claim 23, wherein the density of the holes is at least 0.02 cm⁻².

27. The solar module according to claim 23, wherein the at least one back side foil has a whole area that is provided with the holes.

28. The solar module according to claim 23, wherein further comprising at least one weatherproof foil.

29. The solar module according to claim 23, wherein the at least one back side foil comprises at least one insulation foil.

30. The solar module according to claim 29, further wherein the at least one insulation foil is made of PET.

31. The solar module according to claim 29, further comprising at least one weatherproof foil provided with the holes.

32. The solar module according to claim 31, wherein the at least one weatherproof foil is made of PVF.

33. The solar module according to claim 23, wherein the at least one back side foil comprises a plurality of back side foils all provided with the holes.

34. The solar module according to claim 23, wherein the inter layer comprises an embedment material layer comprising EVA.

35. The solar module according to claim 23, wherein the front pane comprises glass.

36. The solar module according to claim 23, wherein the at least one back side foil is permeable to corrosive substances.

37. The solar module according to claim 36, wherein the corrosive substance is acetic acid.

38. A solar module, comprising:
an inter layer into which solar cells are embedded;
a front pane on a front side of the interlayer;
a plurality of foils on a back side of the interlayer, the plurality of foils comprising a first weather proof foil adjacent the inter layer, a second weather proof foil remote from the interlayer, and an insulation between the first and second weather proof foils; and
a plurality of holes defined in the plurality of foils sufficient to provide permeability to corrosive substances.

39. The solar module according to claim 38, wherein the plurality of holes have a density of at most 0.2 cm⁻².

40. The solar module according to claim 38, wherein the plurality of holes have a density of at least 0.02 cm⁻².

41. The solar module according to claim 38, wherein the plurality of holes have a density of between 0.04 cm⁻² to 0.1 cm⁻².
